(19) United States
(12) Patent Application Publication
(10) Pub. No.: US 2022/0059483 A1
(43) Pub. Date: Feb. 24, 2022

(54) CONDUCTIVE PILLAR BUMP AND MANUFACTURING METHOD THEREFORE

(71) Applicant: Winbond Electronics Corp., Taichung City (TW)

(72) Inventor: Jin-Neng Wu, Taichung City (TW)

(73) Assignee: Winbond Electronics Corp., Taichung City (TW)

(21) Appl. No.: 16/996,826

(22) Filed: Aug. 18, 2020

(51) Int. Cl. H01L 23/00

(52) U.S. Cl. CPC H01L 24/13; H01L 24/11; H01L 24/81; H01L 2224/13015; H01L 2224/13082; H01L 2224/13139; H01L 2224/81801; H01L 2224/13147; H01L 2224/11418; H01L 2224/1145; H01L 2224/11462; H01L 2224/81193; H01L 2224/13144

(57) ABSTRACT

A conductive pillar bump includes a first conductive portion and a second conductive portion. The second conductive portion is located on the first conductive portion. A sidewall of the second conductive portion has at least one trench. The trench extends from a top portion of the second conductive portion to a bottom portion of the second conductive portion. The trench exposes a portion of a top surface of the first conductive portion.

### BACKGROUND OF THE INVENTION

### Field of the Invention

The invention relates to a semiconductor device and a manufacturing method thereof, and particularly relates to a conductive pillar bump and a manufacturing method thereof.

### Description of Related Art

Currently, there are several die attach methods for flip chip bonding technology. Among them, controlling the bonding state of bump in the flip chip bonding process is the key to controlling the yield. For example, in the flip chip bonding process, the solder will be squeezed by the bump (such as the copper pillar bump). When the amount of solder (such as tin) is large, the solder will be squeezed out too much, thus causing the problem of bridging of adjacent solders. In addition, when the amount of solder is too small, it is easy to cause empty welding, or bump cracks occur in the subsequent reliability experiment due to the lack of solder as a buffer.

### SUMMARY OF THE INVENTION

The invention provides a conductive pillar bump and a manufacturing method thereof, which can better control the bonding of the bump to improve the yield.

The invention provides a conductive pillar bump, which includes a first conductive portion and a second conductive portion. The second conductive portion is located on the first conductive portion. A sidewall of the second conductive portion has at least one trench. The trench extends from a top portion of the second conductive portion to a bottom portion of the second conductive portion. The trench exposes a portion of a top surface of the first conductive portion.

The invention provides a method of manufacturing a conductive pillar bump, which includes the following steps. A substrate structure is provided. A first patterned photoresist layer is formed on the substrate structure. The first patterned photoresist layer has a first opening exposing the substrate structure. A first conductive portion is formed on the substrate structure exposed by the first opening. The first patterned photoresist layer is removed. A second patterned photoresist layer is formed on the substrate structure. The second patterned photoresist layer has a second opening exposing the first conductive portion. The second patterned photoresist layer includes at least one protrusion. The protrusion covers a portion of a top surface of the first conductive portion. A second conductive portion is formed on the first conductive portion exposed by the second opening. A sidewall of the second conductive portion has at least one trench. The trench extends from a top portion of the second conductive portion to a bottom portion of the second conductive portion. The second patterned photoresist layer is removed so that the trench exposes the portion of the top surface of the first conductive portion.

The invention provides another method of manufacturing a conductive pillar bump, which include the following steps. A substrate structure is provided. A conductive pillar bump is formed on the substrate structure by a three-dimensional (3D) printing method. The conductive pillar bump includes a first conductive portion and a second conductive portion. The second conductive portion is located on the first conductive portion. A sidewall of the second conductive portion has at least one trench. The trench extends from a top portion of the second conductive portion to a bottom portion of the second conductive portion. The trench exposes a portion of a top surface of the first conductive portion.

Based on the above description, in the conductive pillar bump and its manufacturing method according to the invention, the sidewall of the second conductive portion has at least one trench, and the trench exposes a portion of the top surface of the first conductive portion. Therefore, in the flip chip bonding process, the trench on the second conductive portion can provide more area for solder to attach, thereby reducing the amount of solder squeezed out. In addition, the portion of the top surface of the first conductive portion exposed by the trench can be used as a blocking portion for blocking the solder. Therefore, the portion of the top surface of the first conductive portion exposed by the trench can be used to determine the attachment height of the solder, so that the amount of solder squeezed out can be further controlled. In this way, the bump bonding process can be better controlled to improve the yield.

In order to make the aforementioned and other objects, features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1F are cross-sectional views illustrating a manufacturing process of a conductive pillar bump according to an embodiment of the invention.

FIG. 2A to FIG. 2F are top views of a patterned photoresist layer and/or a conductive portion in FIG. 1A to FIG. 1F, respectively.

FIG. 3 is a top view of a conductive pillar bump according to another embodiment of the invention.

FIG. 4 is a perspective view of the conductive pillar bump in FIG. 1F.

FIG. 5 is a schematic view of a flip chip bonding process according to an embodiment of the invention.

### DESCRIPTION OF THE EMBODIMENTS

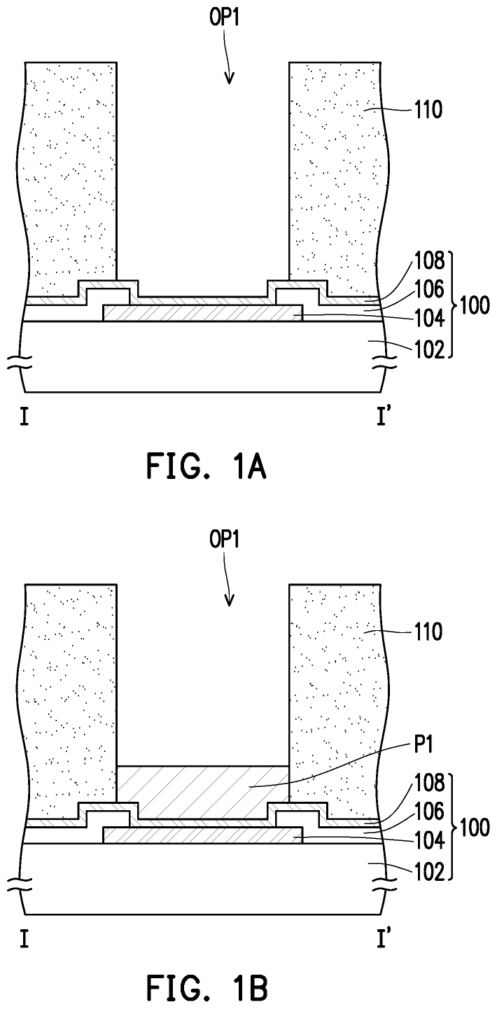

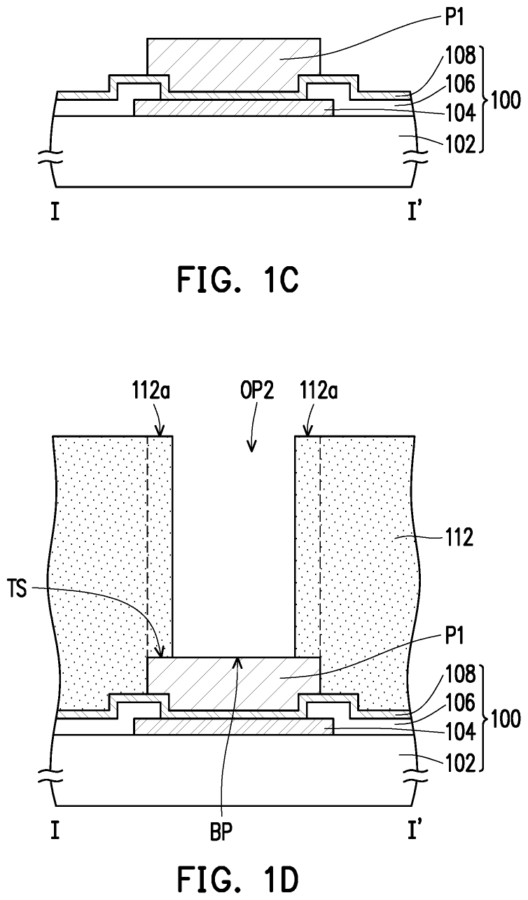

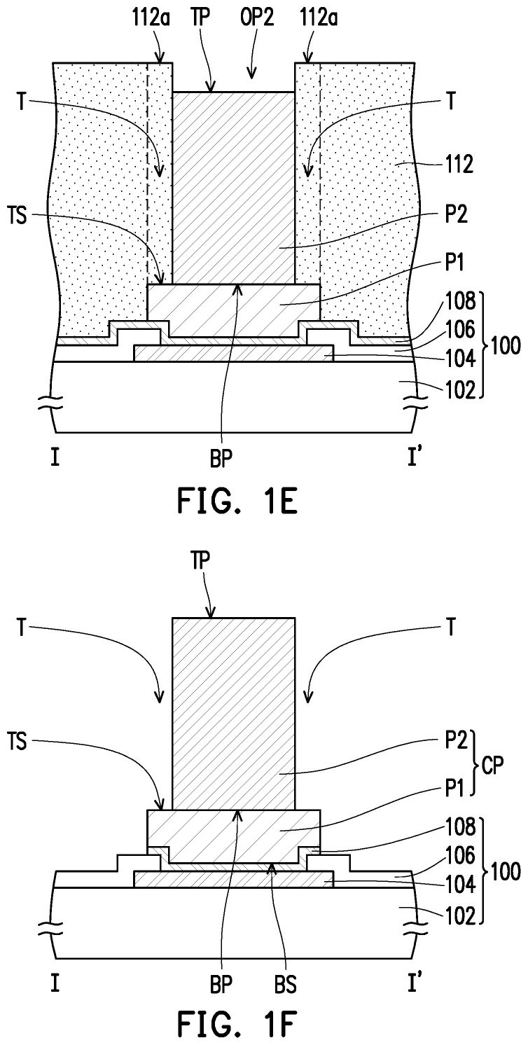

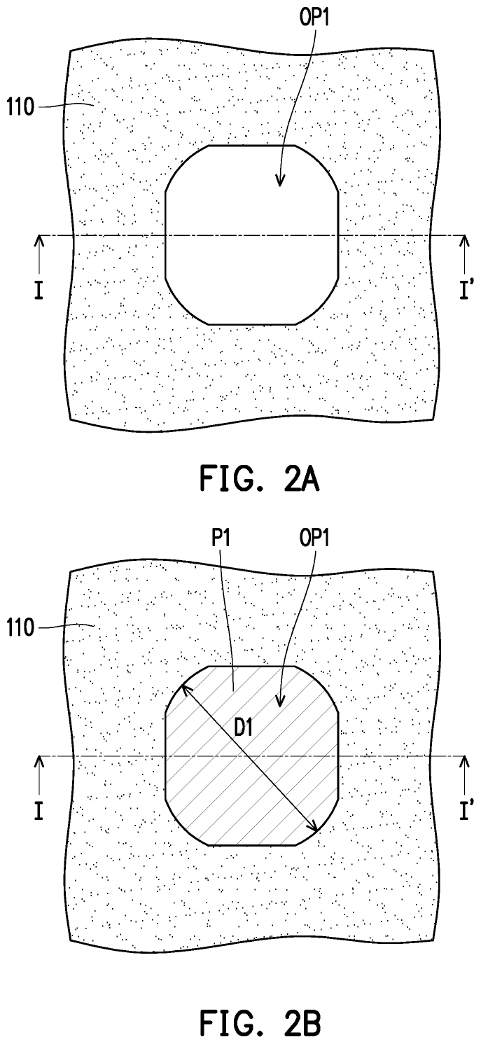

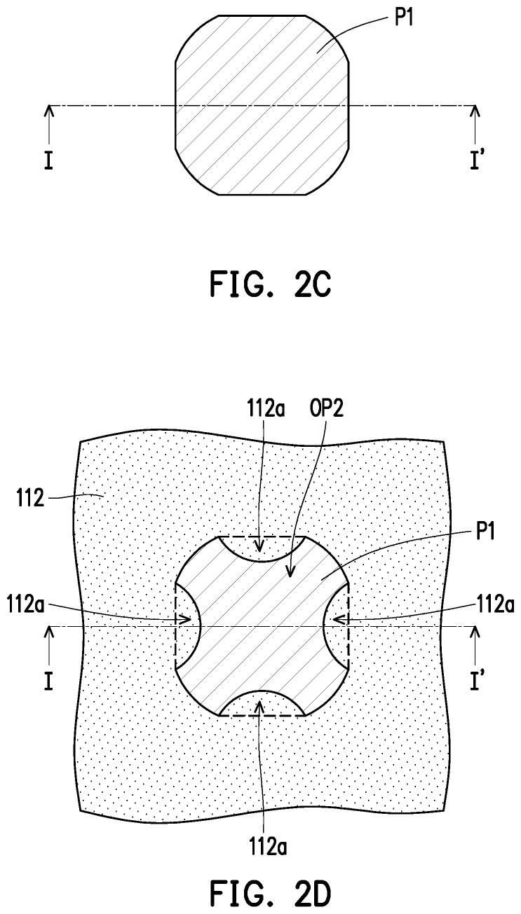

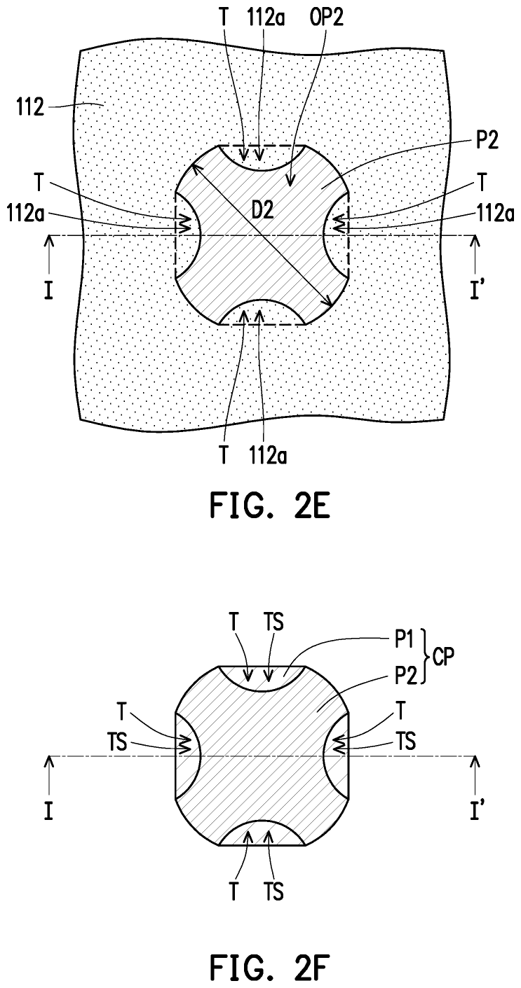

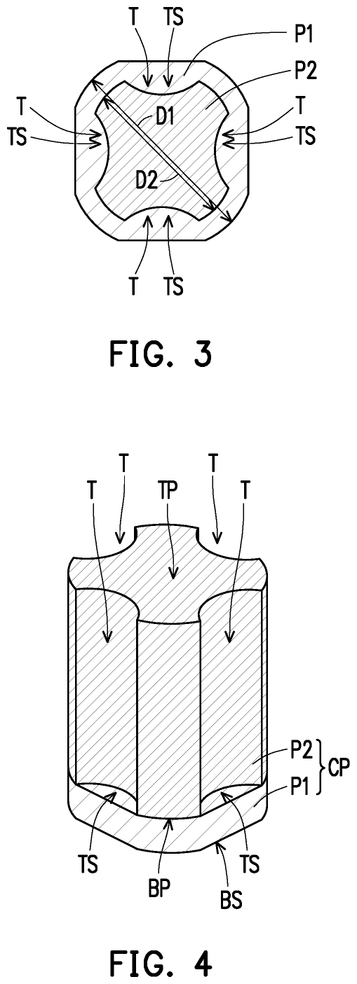

FIG. 1A to FIG. 1F are cross-sectional views illustrating a manufacturing process of a conductive pillar bump according to an embodiment of the invention. FIG. 2A to FIG. 2F are top views of a patterned photoresist layer and/or a conductive portion in FIG. 1A to FIG. 1F, respectively. FIG. 1A to FIG. 1F are cross-sectional views taken along a section line I-I′ in FIGS. 2A to 2F. FIG. 3 is a top view of a conductive pillar bump according to another embodiment of the invention. FIG. 4 is a perspective view of the conductive pillar bump in FIG. 1F.

Referring to FIG. 1A and FIG. 2A, a substrate structure 100 is provided. For example, the substrate structure 100 may be a die. The substrate structure 100 may include a substrate 102, and may further include at least one of a pad 104, a passivation layer 106, and an under bump metallization (UBM) layer 108, but the invention is not limited thereto. The substrate 102 may be a semiconductor substrate such as a silicon substrate. In addition, a required semiconductor device (e.g., an active device or a passive device) (not shown) and a required interconnect structure (not shown) electrically connected to the semiconductor device may be formed on the substrate 102 according to requirements. The pad 104 may be located on the substrate 102 and may be electrically connected to the semiconductor device by the interconnect structure. The material of the pad 104 may include aluminum. The passivation layer 106 may be located on the substrate 102. The material of the passivation layer 106 may include polyimide (PI) or polybenzoxazole (PBO). Furthermore, the passivation layer 106 may cover a portion of the pad 104. That is, the passivation layer 106 may expose a portion of the pad 104. The UBM layer 108 may be located on the pad 104 and the passivation layer 106. The material of the UBM layer 108 may include aluminum, titanium, copper, nickel, tungsten, chromium, gold, tungsten titanium, tin-lead, nickel-vanadium, and/or an alloy thereof.

A patterned photoresist layer 110 is formed on the substrate structure 100. The patterned photoresist layer 110 has an opening OP1 exposing the substrate structure 100. In the present embodiment, the opening OP1 may expose the UBM layer 108 of the substrate structure 100, but the invention is not limited thereto. The patterned photoresist layer 110 may be formed by a lithography process.

Referring to FIG. 1B and FIG. 2B, a conductive portion P1 is formed on the substrate structure 100 exposed by the opening OP1. In the present embodiment, the conductive portion P1 is, for example, formed on the UBM layer 108 of the substrate structure 100, but the invention is not limited thereto. The conductive portion P1 has the maximum diameter D1 (FIG. 2B). The material of the conductive portion P1 may include copper, silver, gold, or an alloy thereof. The method of forming the conductive portion P1 is, for example, an electrochemical plating (ECP) method, an evaporation method, an electroplating method, or a printing method.

Referring to FIG. 1C and FIG. 2C, the patterned photoresist layer 110 is removed. The method of removing the patterned photoresist layer 110 is, for example, a dry stripping method or a wet stripping method.

Referring to FIG. 1D and FIG. 2D, a patterned photoresist layer 112 is formed on the substrate structure 100. The patterned photoresist layer 112 has an opening OP2 exposing the conductive portion P1. The patterned photoresist layer 112 includes at least one protrusion 112a. The protrusion 112a covers a portion of the top surface TS of the conductive portion P1. In the present embodiment, the number of the protrusions 112a is, for example, plural, but as long as the number of the protrusions 112a is at least one, it falls within the scope of the invention. The patterned photoresist layer 112 may be formed by a lithography process.

Referring to FIG. 1E and FIG. 2E, a conductive portion P2 is formed on the conductive portion P1 exposed by the opening OP2. For example, the bottom portion BP of the conductive portion P2 may be located on the top surface TS of the conductive portion P1. The sidewall of the conductive portion P2 has at least one trench T. The trench T extends from the top portion TP of the conductive portion P2 to the bottom portion BP of the conductive portion P2. In the present embodiment, the number of the trenches T is, for example, plural, but as long as the number of the trenches T is at least one, it falls within the scope of the invention. The trenches T may be arranged symmetrically or asymmetrically.

In the present embodiment, the conductive portion P1 and the conductive portion P2 may be independent components. That is, the conductive portion P1 and the conductive portion P2 are formed by different processes rather than being formed continuously, but the invention is not limited thereto. The conductive portion P1 and the conductive portion P2 may be the same material or different materials. The material of the conductive portion P2 may include copper, silver, gold, or an alloy thereof. The method of forming the conductive portion P2 is, for example, an electrochemical plating method, an evaporation method, an electroplating method, or a printing method.

In addition, the conductive portion P2 has the maximum diameter D2 (FIG. 2E). The maximum diameter D2 of the conductive portion P2 may be less than or equal to the maximum diameter D1 of the conductive portion P1 (FIG. 2B). In the present embodiment, the maximum diameter D2 of the conductive portion P2 is, for example, equal to the maximum diameter D1 of the conductive portion P1, but the invention is not limited thereto. In other embodiments, as shown in FIG. 3, the maximum diameter D2 of the conductive portion P2 may be less than the maximum diameter D1 of the conductive portion P1. Furthermore, the shapes and the sizes of the conductive portion P1 and the conductive portion P2 may be adjusted by the opening OP1 of the patterned photoresist layer 110 and the opening OP2 of the patterned photoresist layer 112 according to the product requirements, and are not limited to what is shown in the drawings.

Referring to FIG. 1F and FIG. 2F, the patterned photoresist layer 112 is removed so that the trench T exposes the portion of the top surface TS of the conductive portion P1. The method of removing the patterned photoresist layer 112 is, for example, a dry stripping method or a wet stripping method.

A portion of the UBM layer 108 not covered by the conductive portion P1 may be removed by using the conductive portion P1 as the mask layer. That is, only the UBM layer 108 under the conductive portion P1 is left. A portion of the UBM layer 108 may be removed by an etching process such as wet etching. In the present embodiment, the UBM layer 108 covers a portion of the top surface of the passivation layer 106, but the invention is not limited thereto. In other embodiments, the UBM layer 108 may not cover the top surface of the passivation layer 106. The shape and the size of the UBM layer 108 may be determined by the shape and the size of the conductive portion P1 as the mask layer. In another embodiment, a portion of the UBM layer 108 not covered by the conductive portion P1 may be removed by using an additionally formed mask layer as a mask. In this case, the shape and the size of the UBM layer 108 may be determined by the shape and the size of the additionally formed mask layer.

Hereinafter, the conductive pillar bump CP of the present embodiment is described with reference to FIG. 1F, FIG. 2F, and FIG. 4. In addition, although the method of forming the conductive pillar bump CP is described by taking the above method as an example, the invention is not limited thereto. In other embodiments, the conductive pillar bump CP may be formed on the substrate structure 100 by using the 3D printing method. In the case where the conductive pillar bump CP is formed by the 3D printing method, the conductive portion P1 and the conductive portion P2 may be integrally formed. That is, the conductive portion P1 and the conductive portion P2 may be continuously formed by the same 3D printing process.

Referring to FIG. 1F, FIG. 2F, and FIG. 4, the conductive pillar bump CP includes a conductive portion P1 and a conductive portion P2. The conductive portion P2 is located on the conductive portion P1. The sidewall of the conductive portion P2 has at least one trench T. The trench T extends from the top portion TP of the conductive portion P2 to the bottom portion BP of the conductive portion P2. The trench T exposes the top surface TS of the conductive portion P1. In the present embodiment, the bottom surface BS of the conductive portion P1 is, for example, a convex surface (FIG. 1F), but the invention is not limited thereto. In other embodiments, the bottom surface BS of the conductive portion P1 may be a flat surface. Moreover, the material, the arrangement, and the forming method of each component of the conductive pillar bump CP have been described in detail in the aforementioned embodiments, and the description thereof are not repeated here.

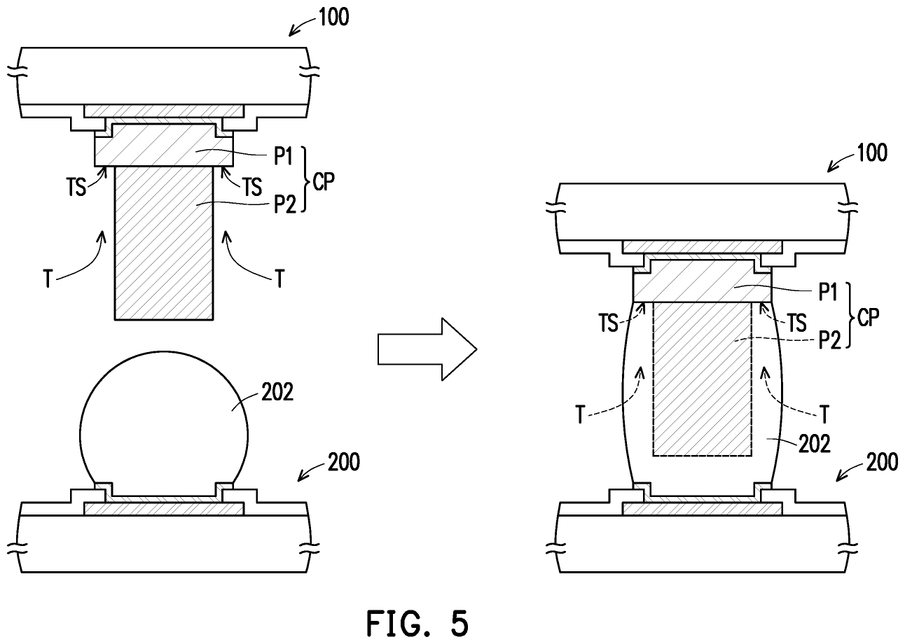

FIG. 5 is a schematic view of a flip chip bonding process according to an embodiment of the invention.

Hereinafter, an embodiment of the flip chip bonding process using the conductive pillar bump CP is described with reference to FIG. 5. Referring to FIG. 5, during the flip chip bonding process, the substrate structure 100 (die) is first aligned with the die 200. In addition, the conductive pillar bump CP is disposed on the substrate structure 100, and a solder 202 is disposed on the die 200. Then, the conductive pillar bump CP and solder 202 are bonded.

Based on the above embodiments, in the conductive pillar bump CP, the sidewall of the conductive portion P2 has at least one trench T, and the trench T exposes a portion of the top surface TS of the conductive portion P1. Therefore, in the flip chip bonding process, the trench T on the conductive portion P2 can provide more area for the solder 202 to attach, thereby reducing the amount of the solder 202 squeezed out. In addition, the portion of the top surface TS of the conductive portion P1 exposed by the trench T can be used as a blocking portion for blocking the solder 202. Therefore, the portion of the top surface TS of the conductive portion P1 exposed by the trench T can be used to determine the attachment height of the solder 202, so that the amount of the solder 202 squeezed out can be further controlled. In this way, the bump bonding process can be better controlled to improve the yield.

In summary, in the conductive pillar bump and its manufacturing method of the aforementioned embodiments, since the conductive pillar bump has a trench and a blocking portion, the amount of solder squeezed out can be reduced by the trench, and the amount of solder squeezed out can be further controlled by the blocking portion, so that the bump bonding process can be better controlled to improve the yield.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A conductive pillar bump, comprising:
a first conductive portion; and
a second conductive portion located on the first conductive portion, wherein a sidewall of the second conductive portion has at least one trench, the at least one trench extends from a top portion of the second conductive portion to a bottom portion of the second conductive portion, and the at least one trench exposes a portion of a top surface of the first conductive portion.

2. The conductive pillar bump according to claim 1, wherein a maximum diameter of the second conductive portion is less than or equal to a maximum diameter of the first conductive portion.

3. The conductive pillar bump according to claim 1, wherein the first conductive portion and the second conductive portion are independent components or are integrally formed.

4. The conductive pillar bump according to claim 1, wherein the first conductive portion and the second conductive portion are the same material.

5. The conductive pillar bump according to claim 1, wherein the first conductive portion and the second conductive portion are different materials.

6. The conductive pillar bump according to claim 1, wherein materials of the first conductive portion and the second conductive portion comprise copper, silver, gold, or an alloy thereof.

7. The conductive pillar bump according to claim 1, wherein the number of the at least one trench is plural, and the trenches are arranged symmetrically.

8. The conductive pillar bump according to claim 1, wherein the number of the at least one trench is plural, and the trenches are arranged asymmetrically.

9. A method of manufacturing a conductive pillar bump, comprising:
providing a substrate structure;
forming a first patterned photoresist layer on the substrate structure, wherein the first patterned photoresist layer has a first opening exposing the substrate structure;
forming a first conductive portion on the substrate structure exposed by the first opening;
removing the first patterned photoresist layer;
forming a second patterned photoresist layer on the substrate structure, wherein the second patterned photoresist layer has a second opening exposing the first conductive portion, the second patterned photoresist layer comprises at least one protrusion, and the at least one protrusion covers a portion of a top surface of the first conductive portion;
forming a second conductive portion on the first conductive portion exposed by the second opening, wherein a sidewall of the second conductive portion has at least one trench, and the at least one trench extends from a top portion of the second conductive portion to a bottom portion of the second conductive portion; and
removing the second patterned photoresist layer so that the at least one trench exposes the portion of the top surface of the first conductive portion.

10. The method of manufacturing the conductive pillar bump according to claim 9, wherein a method of forming the first conductive portion comprises an electrochemical plating method, an evaporation method, an electroplating method, or a printing method.

11. The method of manufacturing the conductive pillar bump according to claim 9, wherein a method of removing the first patterned photoresist layer comprises a dry stripping method or a wet stripping method.

12. The method of manufacturing the conductive pillar bump according to claim 9, wherein a method of forming the second conductive portion comprises an electrochemical plating method, an evaporation method, an electroplating method, or a printing method.

13. The method of manufacturing the conductive pillar bump according to claim 9, wherein a method of removing the second patterned photoresist layer comprises a dry stripping method or a wet stripping method.

14. The method of manufacturing the conductive pillar bump according to claim 9, wherein a maximum diameter of the second conductive portion is less than or equal to a maximum diameter of the first conductive portion.

15. The method of manufacturing the conductive pillar bump according to claim 9, wherein materials of the first conductive portion and the second conductive portion comprise copper, silver, gold, or an alloy thereof.

16. The method of manufacturing the conductive pillar bump according to claim 9, wherein the first conductive portion and the second conductive portion are independent components.

17. A method of manufacturing a conductive pillar bump, comprising:
providing a substrate structure; and
forming a conductive pillar bump on the substrate structure by a three-dimensional printing method, wherein the conductive pillar bump comprises:
a first conductive portion; and
a second conductive portion located on the first conductive portion, wherein a sidewall of the second conductive portion has at least one trench, the at least one trench extends from a top portion of the second conductive portion to a bottom portion of the second conductive portion, and the at least one trench exposes a portion of a top surface of the first conductive portion.

18. The method of manufacturing the conductive pillar bump according to claim 17, wherein a maximum diameter of the second conductive portion is less than or equal to a maximum diameter of the first conductive portion.

19. The method of manufacturing the conductive pillar bump according to claim 17, wherein materials of the first conductive portion and the second conductive portion comprise copper, silver, gold, or an alloy thereof.

20. The method of manufacturing the conductive pillar bump according to claim 17, wherein the first conductive portion and the second conductive portion are integrally formed.
